(19) United States
(12) Patent Application Publication
(10) Pub. No.: US 2026/0052936 A1
(43) Pub. Date: Feb. 19, 2026

(54) FLOW CONTROL APPARATUS AND METHOD

(71) Applicant: Samsung Electronics Co., Ltd., Suwon-si (KR)

(72) Inventors: Seung Hun KIM, Suwon-si (KR); Geon Gu JANG, Suwon-si (KR); Min Jung KIM, Suwon-si (KR); Tae Min KIM, Suwon-si (KR); Ji Ho UH, Suwon-si (KR); Jin Wook LEE, Suwon-si (KR)

(21) Appl. No.: 19/248,983

(22) Filed: Jun. 25, 2025

(30) Foreign Application Priority Data
Aug. 16, 2024 (KR) 10-2024-0109744
Sep. 27, 2024 (KR) 10-2024-0131669

(51) Int. Cl. H01L 21/67; G01F 15/00; G05D 7/06

(52) U.S. Cl. CPC H01L 21/67253; G01F 15/005; G05D 7/0629; H01L 21/67017

(57) ABSTRACT

There is provided a flow control apparatus and a flow control method that may diagnose and compensate for the span error of a mass flow controller to improve the accuracy. The flow control apparatus includes a first valve at an inlet of a fluid conduit, a second valve an outlet end of the fluid conduit, a flow controller which is disposed between the first valve and the second valve, and that includes a pressure sensor and a third valve, and a controller configured to control the first and second valves to be closed and the third valve to be open, sense a rate of decay of the pressure of the fluid using the mass flow controller, and to determine a span error of the flow controller using the rate of decay to derive a compensation value.

### CROSS-REFERENCE TO RELATED APPLICATION

This application claims priority from Korean Patent Application No. 10-2024-0109744 filed on Aug. 16, 2024, and Korean Patent Application No. 10-2024-0131669 filed on Sep. 27, 2024, in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a flow control apparatus and method, and specifically, to an apparatus and method for automatically correcting a span error of a mass flow controller to control a flow rate.

### 2. Description of the Related Art

In a semiconductor manufacturing process, an etching process or a deposition process is performed on a substrate, using a substrate processing apparatus. Fluids used in the etching process or the deposition process are moved to a chamber in which the substrate is disposed through a piping. To improve process repeatability, a set flow rate value of a flow controller should result in a fluid actually flowing at the set flow rate. For example, set flow rate value should be the same as a measured flow rate value measured by a calibrated flow sensor. However, in an actual process, a situation occurs in which the set flow rate value and the actual flow rate value may differ due to a zero shift or span error. This error may occur as a result of an internal flow sensor of a flow controller experiencing a zero shift or span error. Because such errors may cause problems in accurate flow control and management, the errors need to be corrected periodically.

Although manual correction methods may be used to correct the measurement errors of a flow sensor, such as the internal flow sensor of a flow controller, it is difficult to perform an accurate measurement to obtain an accurate correction value, may require additional components and/or modification of existing components, and may be a time-consuming task. Therefore, there is a need for an apparatus and method that may automatically correct the span error of a flow sensor in a flow controller in order to accurately control the flow rate.

### SUMMARY

Aspects of the present disclosure provide a flow control apparatus that may diagnose and compensate for the span error of a mass flow controller.

Aspects of the present disclosure also provide a flow control method that may diagnose and compensate for the span error of a mass flow controller.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a flow control apparatus comprising a first valve at an inlet end of a fluid conduit, a second valve at an outlet end of the fluid conduit, a flow controller disposed between the first valve and the second valve, the flow controller comprising a pressure sensor and a third valve, and a controller configured to control the first valve, the second valve, and the flow controller, and to adjust a set flow rate value (x) of the flow controller, wherein the controller is configured to control the first and second valves to be closed and the third valve to be open, the controller is configured to sense a rate of decay of the fluid using the flow controller, and the controller is configured to calculate a span error of the flow controller using the rate of decay to derive a compensation value.

According to another aspect of the present disclosure, there is provided a flow control apparatus comprising, a first valve connected to an inlet end of a piping, a second valve which is connected to an outlet end of the piping, and spaced apart from the first valve, a flow controller disposed between the first valve and the second valve, and having a pressure sensor and a third valve, a flow control unit configured to adjust a set flow rate value (x) of the flow controller, a function calculation unit configured to calculate a function based on a flow rate sensed from the mass flow controller, a compensation value calculation unit configured to calculate a compensation value, using the function calculated by the function calculation unit, and a controller configured to control the first valve, the second valve, the mass flow controller, the flow control unit, the function calculation unit, and the compensation value calculation unit, wherein the controller is configured to control the first valve and the second valve to be closed and the third valve to be adjusted to a set flow rate value, the function calculation unit is configured to calculate a measured flow rate value (y) defined as a value obtained by multiplying a flow rate conversion coefficient (C) by a rate of decay of the pressure of the fluid flowing between the first valve and the second valve, and the compensation value calculation unit is configured to calculate a span error and a compensation value using the measured flow rate value (y) and the set flow rate value.

According to an aspect of the present disclosure, there is provided a method for adjusting a flow controller comprising, setting a flow controller to a set flow rate value, wherein the flow controller includes a pressure sensor, a control valve, and a flow sensor, closing a valve upstream of the flow controller, measuring the pressure of a fluid between the valve upstream of the flow controller and the control valve, determining a rate of decay of the pressure of the fluid with the upstream valve closed, deriving a measured flow rate of the fluid through the flow controller based on the determined rate of decay and a flow rate conversion coefficient, and calculating a compensation value based on a difference between the set flow rate value and the measured flow rate.

It should be noted that the features and benefits of the present inventive concept are not limited to those described above, and other features and benefits of the present inventive concept will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a diagram showing a semiconductor equipment to which the flow control apparatus according to some embodiments of the present disclosure is applied.

FIG. 2 is a diagram for explaining the flow control apparatus according to some embodiments of the present disclosure.

FIG. 3 is an enlarged view of a portion S of FIG. 1.

FIG. 4 is a diagram for explaining the operation of the flow control apparatus according to some embodiments of the present disclosure.

FIGS. 5 to 8 are diagrams showing a case where the span error is linear.

FIG. 9 is a diagram showing a case where the span error is nonlinear.

FIGS. 10 and 11 are diagrams for explaining a flow control method according to some embodiments of the present disclosure.

FIG. 12 is a diagram for explaining a flow control method according to some embodiments of the present disclosure.

FIG. 13 is a diagram for explaining a flow control method according to some embodiments of the present disclosure.

### DETAILED DESCRIPTION OF THE EMBODIMENTS

Hereinafter, the present disclosure will be described in detail referring to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention. The same reference numerals are used for the same components in the drawings, and their explanations may be provided a single time with the understanding that the description is applicable to other components having the same reference number.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Additionally, when an item having a fluid control feature, such as a fluid channel, a fluid store, a fluid inlet, or a fluid outlet, is described as being connected to another item having a fluid feature, it will be understood that the items are connected to each other a liquid or gas can flow, or be passed, from the fluid feature of one item to the fluid feature of the other, unless the context clearly indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

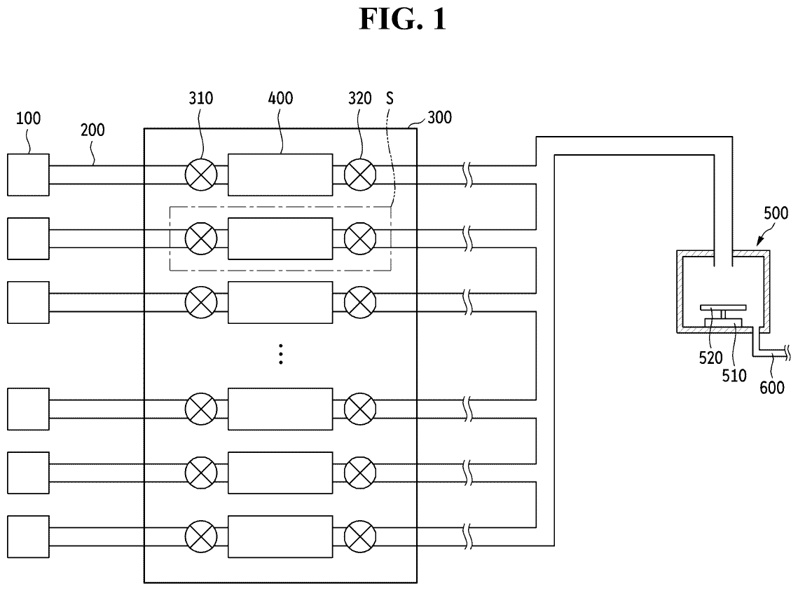

Hereinafter, a flow control apparatus according to some embodiments of the present disclosure will be described referring to FIGS. 1 to 9.

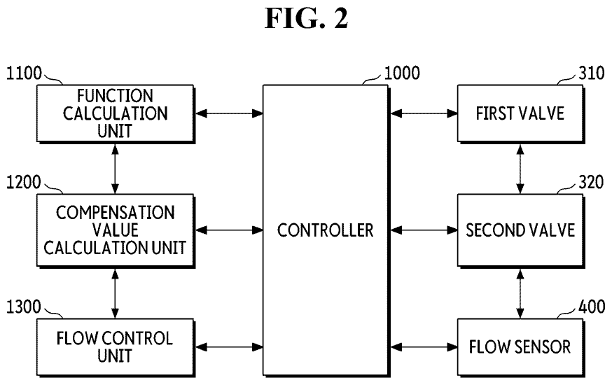

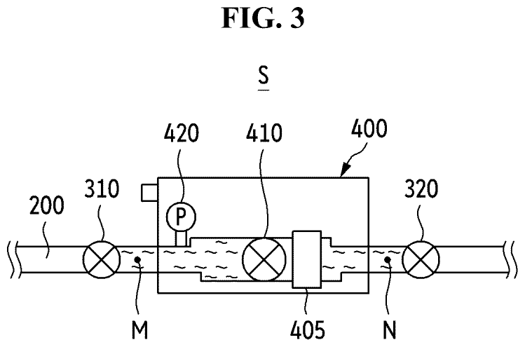

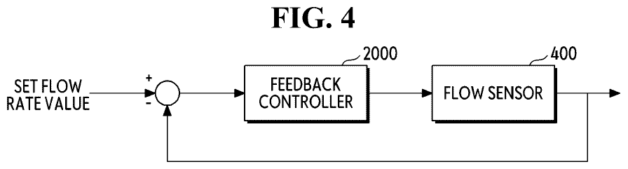

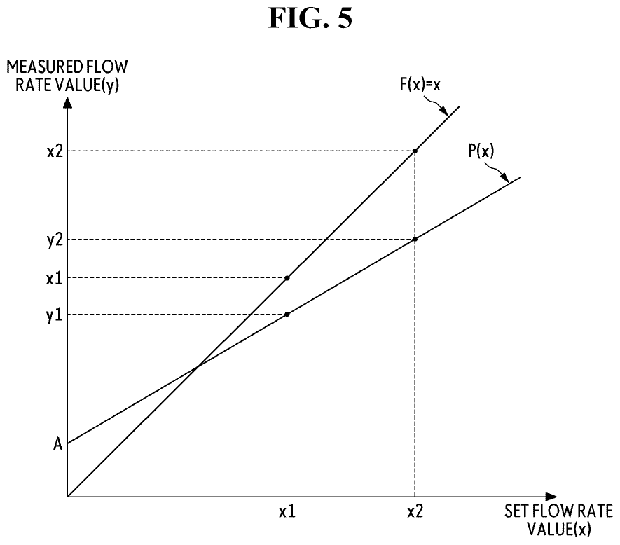

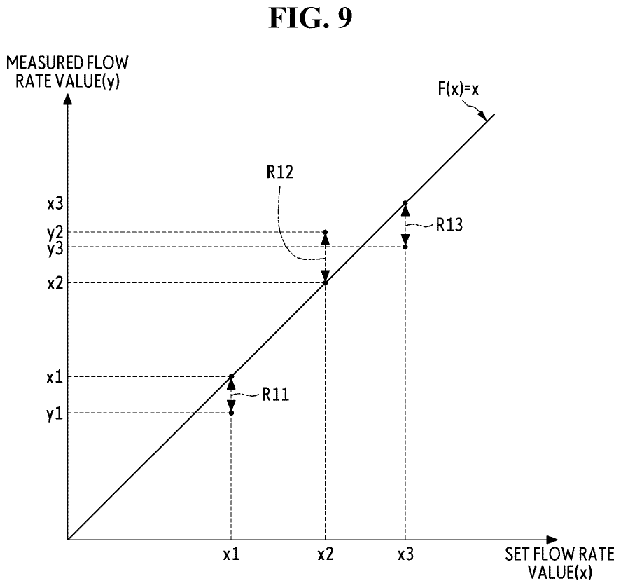

FIG. 1 is a diagram showing semiconductor equipment to which the flow control apparatus according to some embodiments of the present disclosure is applied. FIG. 2 is a diagram for explaining the flow control apparatus according to some embodiments of the present disclosure. FIG. 3 is an enlarged view of a portion S of FIG. 1. FIG. 4 is a diagram for explaining the operation of the flow control apparatus according to some embodiments of the present disclosure. FIGS. 5 to 8 are diagrams showing a relationship between a measured flow rate and a set flow rate in a case where the span error is linear. FIG. 9 is a diagram showing a relationship between a measured flow rate and a set flow rate in a case where the span error is nonlinear.

Referring to FIG. 1, the semiconductor equipment may include a container 100, piping 200, which may include interconnected pipes (e.g., a fluid conduits), a gas box 300, a first valve 310, a second valve 320, a flow controller 400, a process chamber 500, a substrate support 510 for supporting a substrate 520, and a discharge port 600. Each of the container 100, first valve 310, second valve 320, and flow controller 400 may be provided as a plurality.

The semiconductor equipment may perform a semiconductor process on a substrate or other item contained in the process chamber 500. For example, the semiconductor process may include an etching process or a deposition process.

A plurality of containers 100 may be disposed at a first side of the semiconductor equipment. Each of the plurality of containers 100 may be connected to a respective pipe of the piping 200. The plurality of containers 100 may contain a fluid used in the semiconductor process. The fluid used in the semiconductor process may be the same in each of the containers 100 or may vary between the containers 100. For example, the plurality of containers 100 may contain a fluid used in an etching process or a fluid used in a deposition process.

The piping 200 may include passages through which a fluid may move in the semiconductor equipment. The piping 200 may connect the containers 100 and the process chamber 500. The fluid may move from the containers 100 to the process chamber 500 through the piping 200. In FIG. 1, the shape of the piping 200 is shown for convenience of explanation, but is not limited thereto. The shape and number of pipes making up the piping 200, and the like of the piping 200 may vary depending on the semiconductor equipment.

The gas box 300 may cover a part of the piping 200. The first valve 310, the second valve 320, and the flow controller 400 may be disposed inside the gas box 300.

The first valve 310 may be connected to the piping 200. In embodiments with a plurality of first valves 310, second valves 320, and flow controllers 400, each pipe of the piping 200 may be connected to a respective first valve 310, a respective second valve 320, and a respective flow controller 400. The first valves 310 may control the flow of the fluid moving through the pipes in the piping 200. The movement of the fluid may be at least partially controlled depending on whether the first valves 310 are opened or closed. For example, when a first valve 310 is in an opened state, the fluid may move from the respective container 100 through the piping to the respective second valve 320 (e.g., the fluid path is open). When the first valve 310 is in a closed state, the fluid may not move from the container 100 to the second valve 320 (e.g., the fluid path is blocked).

The second valves 320 may be connected to the piping 200. Each second valve 320 may be connected to the piping 200 downstream of a respective first valve 310. The second valves 320 may be disposed apart from the first valves 310 (e.g., downstream from the first valves 310). The second valves 320 may control the flow of the fluid moving through the pipes in the piping 200 (e.g., control the flow of fluid between the first valves 310 and the process chamber 500). The movement of the fluid may be dependent on whether the second valve 320 is opened or closed. For example, when the second valve 320 is opened (e.g., in an open state), the fluid may move from a respective first valve 310 to the process chamber 500. When the second valve 320 is closed (e.g., in a closed state), the fluid may be unable to move from the first valve 310 to the process chamber 500 (e.g., the fluid path is blocked).

The flow controllers 400 may located in a flow path of the piping 200. The flow controllers 400 may be disposed between the first valves 310 and the second valves 320, respectively.

The flow controller 400 may be a mass flow controller. The flow controller 400 may measure the flow rate of the fluid flowing through the flow controller (e.g., measure the mass flow rate of the fluid) and adjust an internal valve to maintain the measured flow rate of the fluid at a set value (e.g., control the flow rate of the fluid based on the measured mass flow rate). The flow controller 400 will be described below in detail.

The process chamber 500 may be connected to the piping 200. The fluid contained in the containers 100 may move to the process chamber 500 through the piping 200. The process chamber 500 may enclose a sealed space that is blocked (e.g., isolated) from the outside environment.

The process chamber 500 may enclose a space in which a semiconductor process is performed. For example, an etching process or a deposition process may be performed on a substrate in the process chamber 500.

The substrate support 510 and the substrate 520 may be disposed inside the process chamber 500. The substrate 520 may be seated on the substrate support 510. The substrate support 510 may support the substrate 520 and rotate the substrate 520 during the semiconductor process.

The discharge port 600 may be connected to the process chamber 500. Fluids used in the semiconductor process may be discharged to outside of the process chamber 500 through the discharge port 600. The discharge port 600 may discharge gas, vapor by-products, and the like generated inside the process chamber 500.

Although the discharge port 600 is shown as being connected to the lower end of the process chamber 500 in FIG. 1, embodiments are not limited thereto. In other embodiments, the discharge port 600 may be connected to an upper end or a side face of the process chamber 500.

FIG. 2 is a diagram of a flow control apparatus according to some embodiments. The flow control apparatus may include a first valve 310, a second valve 320, a flow controller 400, a flow control unit 1300, a function calculation unit 1100, a compensation value calculation unit 1200, and a controller 1000. Although FIG. 2 shows singular elements, it will be understood that the description is application to embodiments with pluralities of the elements.

The controller 1000 may be a computer (or several interconnected computers) and may include, for example, one or more computer processors configured by software, and the flow control unit 1300, the function calculation unit 1100, and the compensation value calculation unit 1200 may be functional modules of the controller 1000. In some examples, one or more of the flow control unit 1300, the function calculation unit 1100, and the compensation value calculation unit 1200 be separate from the controller 1000 and may be implemented by a computer dedicated to that purpose. The controller 1000 may be a general purpose computer or may be dedicated hardware or firmware (e.g., an electronic or optical circuit, such as application-specific hardware, such as, for example, a digital signal processor (DSP) or a field-programmable gate array (FPGA)). The controller 1000 may be configured from several interconnected computers. Each functional module (or unit) described herein may comprise a separate computer, or some or all of the functional module (or unit) may be comprised of and share the hardware of the same computer. Connections and interactions between the units described herein may be hardwired and/or in the form of data (e.g., as data stored in and retrieved from memory of the computer, such as a register, buffer, cache, storage drive, etc., such as part of an application programming interface (API)). The functional modules (or units) of the controller may each correspond to a separate segment or segments of software (e.g., a subroutine) which configure the computer of the controller 1000, and/or may correspond to segment(s) of software that also correspond to one or more other functional modules (or units) described herein (e.g., the functional modules (or units) may share certain segment(s) of software or be embodied by the same segment(s) of software). As is understood, “software” refers to prescribed rules to operate a computer, such as code or script. The controller may include conventional storage for storing computer software such as a hard drive (which may be a solid state drive, DRAM, NAND flash memory, etc.) and the storage may be non-transitory.

FIG. 3 is a diagram of a gas box 300 of a flow control apparatus according to some embodiments. Although the gas box 300 shown in FIG. 3 shows a single first valve 310, single second valve 320, and single flow controller 400, it will be understood that the description is applicable to embodiments with pluralities of the respective elements in the gas box 300.

The first valve 310 and the second valve 320 may be spaced apart from each other, and may be connected to the piping 200. For example, the piping 200 may include a fluid channel between the first valve 310 and the second valve 320, with the first valve 310 being positioned at the inlet end and the second valve being positioned at the outlet end. The state of the first valve 310 and the second valve 320 may determine whether the fluid is able to flow through the piping (e.g., may allow or inhibit fluid from flowing into the inlet end and/or the outlet end). The first valve 310 and the second valve 320 may be selectively closed or opened (e.g., may be operated to change between an opened state and a closed state) and they may close and open in coordination with one another. The first valve 310 and the second valve 320 may be selectively opened and closed based on a control signal generated by the controller 1000.

The flow controller 400 may be connected to the piping 200 between the first valve 310 and the second valve 320. The flow controller 400 may include a flow sensor 405, a pressure sensor 420 and a third valve 410. The flow sensor 405 may be a mass flow sensor.

The pressure sensor 420 may be disposed closer to the first valve 310 than the second valve 320. The pressure sensor 420 may measure a pressure of the fluid in the piping 200 at a location between the first valve 310 and the second valve 320. The pressure sensor 420 may be located between the first valve 310 and the third valve 410 and may measure the pressure in a fluid channel of the piping 200 between the first valve 310 and the third valve 410. The pressure sensor 420 may continuously measure the pressure of the fluid in the piping between the first valve 310 and the third valve 410. The pressure measured by the pressure sensor 420 may be used to determine a rate of decay of the fluid, such as a rate of decay of the pressure of the fluid.

The flow sensor 405 may measure the flow rate of the fluid as it passes through the flow controller 400. The flow sensor 405 may be a mass flow sensor such as a differential pressure, differential temperature, Coriolis, ultrasonic, electromagnetic, turbine, or other type of sensor that measures the mass flow of a fluid. The flow controller 400 may adjust the third valve 402 in response to the flow rate measured by the flow sensor 405 to open the third valve 402 an amount that results in the flow rate of the fluid passing through the flow controller 400 to be at a set flow rate value as measured by the flow sensor 405.

The third valve 410 may be disposed between the first valve 310 and the second valve 320. The third valve 410 may be a control valve that is continuously adjustable or incrementally adjustable between an open state and a closed state. The flow rate of the fluid between the first valve 310 and the second valve 320 may be dependent on the state of the third valve 410 (e.g., the flow rate of the fluid may increase when the third valve 410 is adjusted to approach the open state and may decrease when the third valve 410 is adjusted to approach the closed state). The third valve 410 may play a role in controlling the flow rate of the fluid. For example, when the third valve 410 is fully open, the fluid may be able to move unrestricted from the first valve 310 to the second valve 320, and when the third valve 410 is closed, the fluid may be unable to move from the first valve 310 to the second valve 320. The third valve 410 may have states other than open and closed (e.g., partially open). The flow of the fluid through the pipe may be restricted by the third valve 410 to control the flow rate of the fluid to be at the set flow rate.

The flow control unit 1300 may adjust the third valve 410 so that the flow rate measured by the flow sensor 405 is at the set flow rate value. For example, a target flow rate may be input by a user and the controller 1000 may send the target flow rate to the flow control unit 1300, which may then determine a set flow rate value for the flow controller 400 that results in the target flow rate. If the flow sensor 405 were ideal, the flow control unit 1300 would set the set flow rate value to the target flow rate value. However, since the flow sensor 405 may have span errors and a zero offset, the flow control unit 1300 may compensate for the errors using a compensation value such that the set flow rate value may differ from the target flow rate value. For example, the flow control unit 1300 may set the set flow rate value for the flow controller 400 based on the target flow rate value and at least one compensation value. The set flow rate value set by the flow control unit 1300 may be defined as a set flow rate value x.

The function calculation unit 1100 may calculate a function, using numerical values correlated with the rate of decay RoD of the pressure as sensed by the pressure sensor of the flow controller 400. The function may be a function that correlates the rate of decay RoD of the pressure with a flow rate of interest, such as a mass flow rate. The function calculation operation of the function calculation unit 1100 will be described below in detail.

The compensation value calculation unit 1200 may calculate a compensation value, using the function calculated by the function calculation unit 1100. The compensation value calculation operation of the compensation value calculation unit 1200 will be described below. The compensation value may be a value that can be used to adjust the output of the flow sensor 405 to be more accurate (e.g., closer to an actual flow rate), or adjust the set flow rate value to a value that results in an actual flow rate that is closer to the target flow rate value.

The controller 1000 may control the operation of the first valve 310, the second valve 320, the flow controller 400, the flow control unit 1300, the function calculation unit 1100, and the compensation value calculation unit 1200 (e.g., the controller 1000 may communicate with the components to send and/or receive control signals to and/or from the elements). The set flow point value may be represented by a signal sent to the flow controller 400. For example, the controller 1000 may send a control signal to the first valve 310 to open or close the first valve 310. The controller 1000 may send a control signal to the second valve 320 to open or close the second valve 320. The controller 1000 may receive a signal from the flow controller 400 from which the flow rate can be measured (e.g., the flow sensor 405 of the flow controller 400). The controller 1000 may receive a signal from the pressure sensor 420 of the flow controller 400 to determine the rate of decay of the pressure of the fluid. The controller 1000 may send a control signal to the third valve 410 included in the flow controller 400 to change the amount the third valve 410 is opened (e.g., a control signal corresponding to the set flow point value). The controller 1000 may send the control signal to the third valve 410 by way of the flow control unit 1300. The controller 1000 may control the flow control unit 1300 to determine the set flow rate value x to send to the flow controller 400. The controller 1000 may control the function calculation unit 1100 to calculate a function for correcting measurement errors of the flow sensor 405 in the flow controller 400. The controller 1000 may control the compensation value calculation unit 1200 to calculate the compensation value.

The correction operation of the flow control apparatus according to some embodiments of the present disclosure will be described below, referring to FIGS. 4 to 9.

The operation of the flow control apparatus may be as follows. As will be described hereafter, the flow control apparatus may derive a flow rate conversion coefficient and a measured flow rate value. The flow control apparatus may compare the measured flow rate value with a set flow rate value to calculate a compensation value. The compensation value is a value that the controller 1000 may use to adjust the set flow rate value to compensate for a difference in the target flow rate value and the actual flow rate. The compensation value may include a first compensation value and/or a second compensation value. The flow control apparatus may use the first compensation value to compensate for an error in the flow sensor 405 of the flow controller 400 through the feedback controller 2000. The flow control apparatus may use the second compensation value to set a new set flow rate value. The flow control apparatus according to some embodiments of the present disclosure may correct the flow rate measurement value of the mass flow sensor or reset the set flow rate value.

The operation of the above flow control apparatus will be described below in detail.

The flow control apparatus may derive a flow rate conversion coefficient C as follows. The flow rate conversion coefficient C may be determined at an initial time when the flow sensor 405 of the flow controller 400 is in a known calibrated state. Thus, at this time the measured mass flow measured by the flow sensor 405 is known to be accurate. The flow rate conversion coefficient C is dependent on the physical geometry of the fluid channel between the first valve 302 and the second valve 304 and should not change unless the geometry is changed. Thus, once determined, there may not be any need to determine the rate conversion coefficient C again.

In the process of determining the rate conversion coefficient C, the controller 1000 may control the first valve 310 and the second valve 320 to both be closed and the flow controller 400 is adjusted to an initial set flow rate. With the first valve 310 and the second valve 320 closed and the flow controller 400 set to the initial set flow rate, the fluid may continue to flow through the flow controller 400 from a first point M upstream of the flow controller 400 to a second point N downstream of the flow controller 400 at a flow rate controlled by the flow controller 400 until the pressure on each side of the flow controller 400 is equalized.

In the state in which the first valve 310 and the second valve 320 are closed and the flow controller 400 is set to the initial set flow rate value, the pressure sensor 420 included in the flow controller 400 may sense an initial rate of decay RoDi of the pressure of the fluid. For example, since the volume is constant in the fluid channel between the first valve 310 and the third valve 410, the rate of decay RoD of the pressure can be correlated to a change in the mass of the fluid in the fluid channel between the first valve 310 and the third valve 410. The initial rate of decay RoDi of the pressure as measured by the pressure sensor 420 may be correlated to the initial measured flow rate value yi as measured by the flow sensor 405. This initial measured flow rate value yi is known to be accurate at the time the flow sensor 405 is calibrated.

The flow rate conversion coefficient C may be calculated using the following Formula (1). The flow rate conversion coefficient C may correlate the rate of decay of the pressure with the flow rate of the fluid.

C=(yi+L)/RoDi [Formula 1]

In [Formula 1], L may be leakage of the first valve 310 and the second valve 320. L may be ignored in general conditions (e.g., L may be insignificant compared to the flow rate through the flow controller 400). The flow rate conversion coefficient C may be derived by [Formula 1] from the initially measured flow rate value (yi) that is reliable at the initial time and the initial rate of decay RoDi determined at the initial time. The flow rate conversion coefficient may be used in the same way for the same type of equipment and component (e.g., should not change).

Once the flow rate conversion coefficient C has been determined, the flow control apparatus may use the rate of decay RoD of the pressure to derive a measured flow rate value y using the rate of decay RoD sensed by the pressure sensor 420 and the flow rate conversion coefficient C.

The measured flow rate value y may be derived using Formula (2).

y=C×RoD [Formula 2]

Here, C is the flow rate conversion coefficient that was found previously, and RoD may be a rate of decay of the fluid pressure based on the pressure measured by the pressure sensor 420 when determining the flow rate.

Since the measured flow rate value y is a value that can be obtained at more than one measurement, a plurality of values (y1, y2, y3, etc.) may be derived.

The flow control apparatus according to some embodiments of the present disclosure may operate differently in a case where the measured flow rate values have a linear relationship and a case where they have nonlinear relationship. The flow control apparatus may derive a compensation value differently in a case where the span error is linear and in a case where it is nonlinear.

FIGS. 5 to 7 are diagrams showing the relation between the measured flow rate value y and the set flow rate value x in a case where the span error is linear.

Referring to FIG. 5, when the span error has a linear relationship, the function calculation unit 1100 may derive a calculation function P(x) and an ideal function F(x) as follows, using first flow rate bands (x1, y1) and second flow rate bands (x2, y2). The function calculation unit 1100 may derive the calculation function P(x) from the first set flow rate value x1, a first measured flow rate value y1, the second set flow rate value x2, and the second measured flow rate value y2.

P(x)=((y2−y1)/(x2−x1))x+A Calculation function

F(x)=x Ideal function

In this example, the independent variable x is an arbitrary set flow rate value. x1 is a first set flow rate value, and y1 is an initially measured flow rate value corresponding to x1. x2 is a second set flow rate value, and y2 is a second measured flow rate value corresponding to x2. A is a zero shift value.

In an ideal case, the set flow rate value x is the same as the measured flow rate value y. However, if the span error is distorted or a zero shift occurs, the set flow rate value x may differ from the measured flow rate value y.

The calculation function P(x) is a function derived using the flow rate conversion coefficient C, the measured rate of decay RoD, the set flow rate value x, and the measured flow rate value y (as determined by the measured rate of decay RoD).

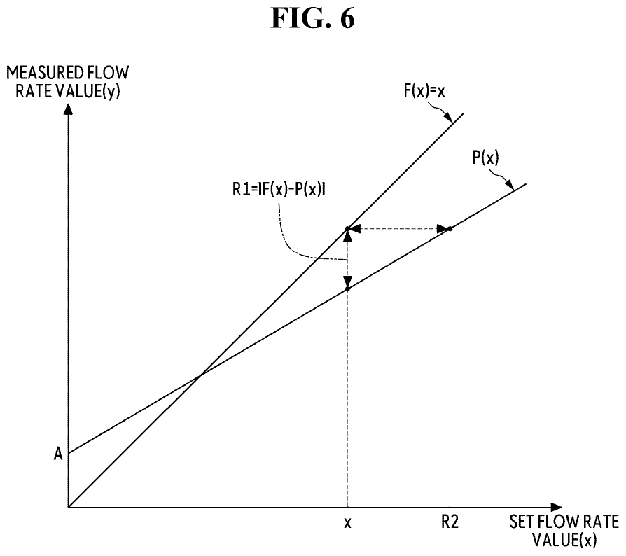

Referring to FIG. 6, the compensation value calculation unit 1200 may calculate the compensation value by comparing the ideal function F(x) obtained in FIG. 5 with the calculation function P(x). The compensation value may include a first compensation value R1 and/or a second compensation value R2. The first compensation value R11 can be used to modify the flow rate value measured by the flow sensor 405 so that the modified flow rate value is closer to the actual flow rate value. The second compensation value R2 can be used to adjust the flow rate set value to a set value that results in a flow rate that is nearer to the actual flow rate.

The first compensation value R1 may be calculated as follows.

The first compensation value R1 may be a difference between the ideal function F(x) and the calculation function P(x) at a set flow rate x. For example, the first compensation value R1 may be the value of the difference between the ideal function F(x) and the calculation function P(x) at an arbitrary set flow rate value x. For example, the first compensation value R1 may be F(x)−P(x).

The compensation value calculation unit 1200 may use the first compensation value R1 as feedback for measurements made by the flow sensor 405 of the flow controller 400. For example, if the measured flow rate value obtained from the calculation function P(x) at an arbitrary set flow rate value x is different from the ideal flow rate value obtained from the ideal function F(x), the difference between the ideal flow rate value of the ideal function F(x) and the measured flow rate value of the calculation function P(x) may be compensated for when measuring the flow rate with the flow sensor 405 of the flow controller 400.

The second compensation value R2 may be calculated as follows.

The second compensation value R2 may be a new set flow rate value at which the measured flow rate value of the calculation function P(x) becomes equal to the measured flow rate value of the ideal function F(x).

For example, for the calculation function P(x), the component (y2−y1)/(x2−x1) may be defined as B. The calculation function P(x) may be expressed as follows.

P(x)=Bx+A Calculation function

The set flow rate value R2 at which the measured flow rate values of the calculation function P(x) becomes equal to the ideal function F(x) may be expressed as follows.

R2=(x−A)/B

Here, x may be an arbitrary set flow rate value, A may be a zero shift value, and B may be (y2−y1)/(x2−x1), which is a slope of the calculation function P(x).

The compensation value calculation unit 1200 may transfer the second compensation value R2 to the flow control unit 1300. The flow control unit 1300 may reset (e.g., change) the set flow rate value x to the second compensation value R2.

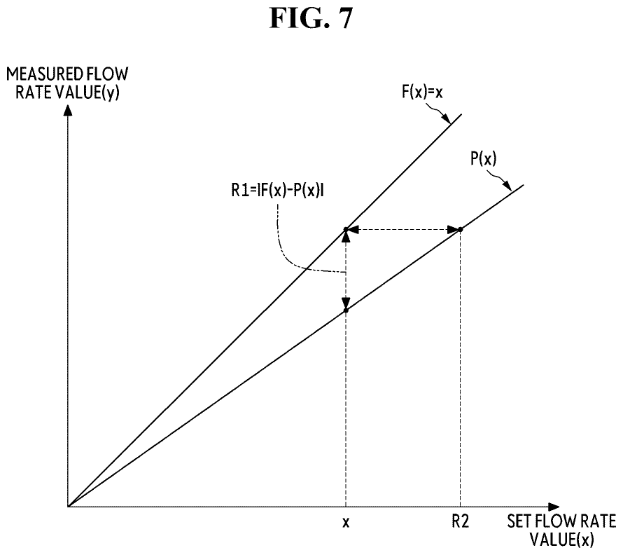

FIG. 7 is a diagram showing a graph assuming that the zero shift value A is 0 in the calculation function P(x). There are two types of errors (span error and zero shift) in the sensor, but FIG. 7 focuses on the span error and assumes that there is no zero shift for convenience.

Referring to FIG. 7, the compensation value calculation unit 1200 may calculate a compensation value by comparing the ideal function F(x) with the calculation function P(x). The compensation value may include a first compensation value R1 and a second compensation value R2.

The first compensation value R1 may be a difference between the ideal function F(x) and the calculation function P(x). For example, the first compensation value R1 may be the absolute value of the difference between the ideal function F(x) and the calculation function P(x) at an arbitrary set flow rate value x. That is, the first compensation value R1 may be F(x)−P(x).

The compensation value calculation unit 1200 may feed the first compensation value R1 to the flow sensor 405 of the flow controller 400 to control the flow rate.

The second compensation value R2 may be a new set flow rate value at which the measured flow rate value of the calculation function P(x) becomes equal to the measured flow rate value of the ideal function F(x).

For example, in the calculation function P(x), (y2−y1)/(x2−x1) may be defined as B.

The set flow rate value R2 at which the measured flow rate values of the calculation function P(x) and the ideal function F(x) become equal to each other may be expressed as follows.

R2=x/B

Here, x may be an arbitrary set flow rate value, and B may be (y2−y1)/(x2−x1), which is the slope of the calculation function P(x).

The compensation value calculation unit 1200 may transfer the second compensation value R2 to the flow control unit 1300. The flow control unit 1300 may reset the set flow rate value x to the second compensation value R2.

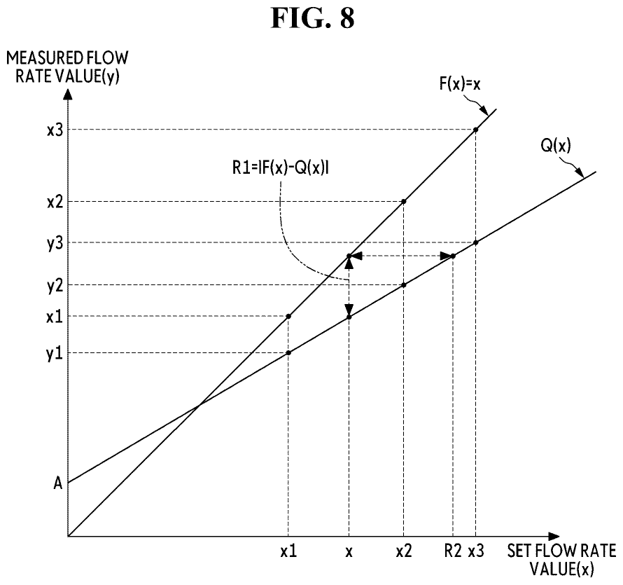

FIG. 8 is a diagram showing a case where the span error is linear and the flow rate bands are three or more. That is, this is a diagram for explaining a case where the span error and the compensation value are derived for two or more set flow rates (x1, x2, x3, etc.) and two or more measured flow rates (y1, y2, y3, etc.).

Referring to FIG. 8, the function calculation unit 1100 may calculate a calculation function Q(x) using a linear regression analysis.

In the case of three or more flow rate bands ((x1, y1), (x2, y2), (x3, y3)), the function calculation unit 1100 may derive the calculation function Q(x) and the ideal function F(x) by the linear regression analysis as follows.

Q(x)=Cx+A Calculation function

F(x)=x Ideal function

Here, the independent variable x is an arbitrary set flow rate value. C is a slope of the calculation function Q(x) obtained by the linear regression analysis. C may represent the span error. A is the zero shift value.

The compensation value calculation unit 1200 may calculate the compensation value, using the ideal function F(x) and the calculation function Q(x) of FIG. 8. The compensation value may include a first compensation value and a second compensation value.

The first compensation value R1 may be a difference between the ideal function F(x) and the calculation function Q(x). The first compensation value R1 may be an absolute value of the difference between the ideal function F(x) and the calculation function Q(x) at an arbitrary set flow rate value x. That is, the first compensation value R1 may be F(x)−Q(x). The first compensation value R1 may be fed back to the flow sensor 405 of the flow controller 400 to adjust the flow rate.

The second compensation value R2 may be a new set flow rate value at which the measured flow rate value of the calculation function Q(x) becomes equal to the measured flow rate value of the ideal function F(x). The second compensation value R2 may be R2=(x−A)/C. The compensation value calculation unit 1200 may transfer the second compensation value R2 to the flow control unit 1300. The flow control unit 1300 may reset the set flow rate value x to the second compensation value R2.

FIG. 9 is a diagram showing a case where the span error is nonlinear.

When the span error is nonlinear, the compensation value calculation unit 1200 may derive a compensation value for each of the measured flow rate values y1, y2, and y3. The compensation value may include first compensation values R11, R12, and R13 and a second compensation value.

The first compensation values R11, R12, and R13 may be a difference between the set flow rate value x and the measured flow rate value y.

For example, according to the ideal function F(x), the ideal measured flow rate value x1 needs to be derived by the first set flow rate value x1. However, the first measured flow rate value y1 corresponding to the first set flow rate value x1 may be measured due to the span error. In this case, the first compensation value R11 may be a difference between the first set flow rate value x1 and the first measured flow rate value y1.

As another example, according to the ideal function F(x), the ideal measured flow rate value x2 needs to be derived by the second set flow rate value x2. However, the second measured flow rate value y2 corresponding to the second set flow rate value x2 may be measured due to the span error. In this case, the first compensation value R12 may be a difference between the first set flow rate value x2 and the first measured flow rate value y2.

As yet another example, according to the ideal function F(x), an ideal measured flow rate value x3 needs to be derived by the third set flow rate value x3. However, a third measured flow rate value y3 corresponding to the third set flow rate value x3 may be measured due to the span error. In this case, the first compensation value R13 may be a difference between the third set flow rate value x3 and the third measured flow rate value y3.

The compensation value calculation unit 1200 may feed back each of the first compensation values R11, R12, and R13 to the flow controller 400. For example, each of the first compensation values R11, R12, and R13 may be fed back to the flow controller 400 to control the flow rate.

The second compensation value may be derived by following Formula (3) for the set flow rate value x and the measured flow rate value y.

Second compensation value=x²/y [Formula 3]

The second compensation values in each of the flow rate bands ((x1, y1), (x2, y2), (x3, y3)) of FIG. 9 may be x12/y1, x22/y2, and x32/y3, respectively.

The compensation value calculation unit 1200 may transfer the second compensation value to the flow control unit 1300. The flow control unit 1300 may reset the set flow rate value x to the second compensation value.

For example, if a measured flow rate value of 55 is measured at a set flow rate value of 50, the second compensation value may be 45.45 according to the above Formula 3. If the set flow rate value is reset to 45.45, a measured flow rate value of 50 may be derived.

In a semiconductor process including an etching process, a deposition process or a cleaning process, a fluid may move to a process chamber through the piping. In the semiconductor process, the degree of etching, the degree of deposition or the degree of cleaning may be determined depending on the flow rate of the fluid. Therefore, the difference between the set flow rate value and the measured flow rate value needs to be within an error range. However, a span error may occur in the flow sensor depending on the usage environment. A difference occurs between the set flow rate and the actual flow rate due to the span error, and such a span error causes a semiconductor process dispersion.

However, the flow control apparatus according to some embodiments of the present disclosure may improve the accuracy of flow rate measurement, by automatically correcting the span error of the flow sensor, using a unique valve operation sequence and the rate of decay of the fluid in the piping. For example, the flow control apparatus may close the first and second valves and open the third valve. In this case, the MFC located between the first and second valves may measure the rate of decay of the fluid, using a pressure sensor. A flow rate conversion coefficient may be derived through the initial rate of decay of the fluid and the initial flow rate measured value. A measured flow rate value y defined as a flow rate change coefficient and a rate of decay during measurement may be derived. A compensation value may be derived separately into a linear case and a nonlinear case of a span error between the measured flow rate value y and the set flow rate value x. The compensation value may be fed back to the flow sensor or the flow control unit. The flow control apparatus according to some embodiments of the present disclosure may more precisely control the flow rate of the fluid to enhance the efficiency of a semiconductor process and improve the safety and reliability of semiconductor equipment.

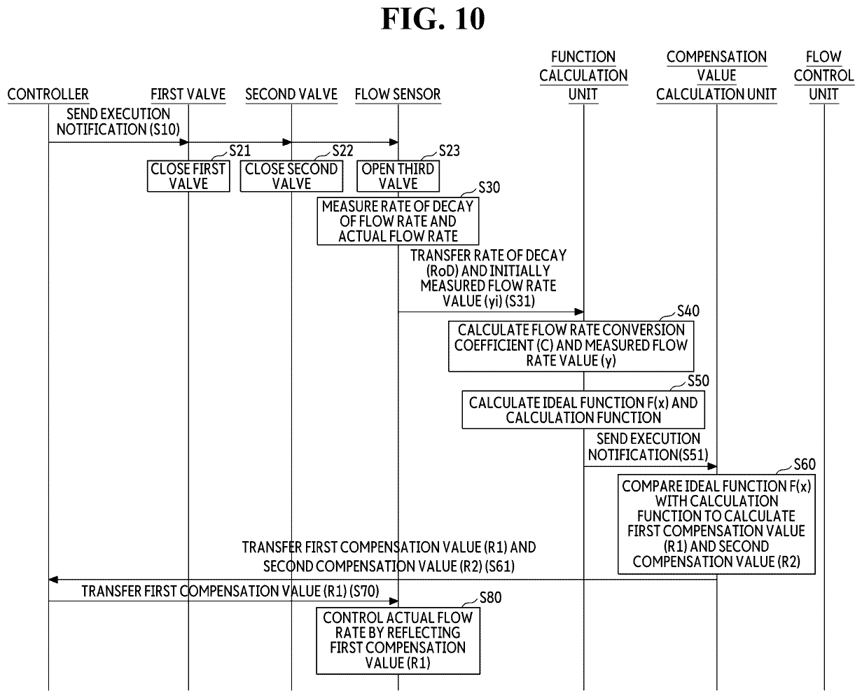

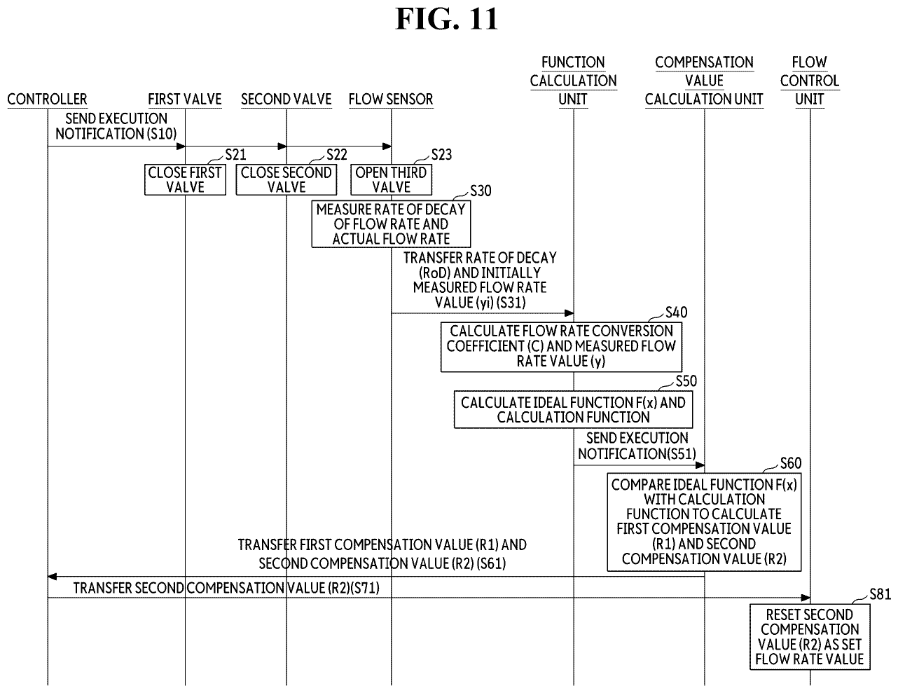

FIGS. 10 and 11 are diagrams for explaining a flow control method according to some embodiments of the present disclosure. For convenience of explanation, repeated contents of those explained in FIGS. 1 to 9 will be briefly explained or omitted.

Referring to FIGS. 10 and 11, the controller 1000 sends an execution notification to the first valve 310, the second valve 320, and the flow controller 400 (S10). The first valve 310 and the second valve 320 that have received the execution notification close the first valve 310 and the second valve 320 (S21, S22). The flow controller 400 that has received the execution notification sets the third valve 410 (S23) to a set flow rate x.

Next, the flow controller 400 measures the rate of decay of the pressure from which the flow rate can be determined and measures the flow rate using the flow sensor 405 to find the actual flow rate (S30). The flow controller 400 transfers the measured rate of decay RoD and the initially measured flow rate value yi to the function calculation unit 1100 (S31).

Next, the function calculation unit 1100 calculates the flow rate conversion coefficient C using the measured flow rate value y (S40).

The flow rate conversion coefficient C may be calculated using the initial rate of decay RoDi and the initially measured flow rate value yi. For example, the flow rate change coefficient C may be calculated by following [Formula 1].

C=(yi+L)/RoDi (the leakage L of the first valve 310 and the second valve 320 is ignored.) [Formula 1]

The measured flow rate value y may be calculated by following Formula (2).

y=C×RoD [Formula 2]

Here, C is the flow rate conversion coefficient, and RoD may be the rate of decay sensed from the pressure sensor 420 at the time of the flow rate measurement.

The function calculation unit 1100 may calculate the calculation function using a plurality of measured flow rate values y. When the span error is linear, the calculation function may include a calculation function P(x) (see FIG. 5) calculated at two measurement points ((x1, y1), (x2, y2)), three or more measurement points ((x1, y1), (x2, y2), (x3, y3), etc.), and a calculation function Q(x) (see FIG. 8) calculated by the linear regression analysis.

Next, the function calculation unit 1100 sends an execution notification to the compensation value calculation unit 1200 (S51). The compensation value calculation unit 1200 compares the ideal function F(x) with the calculation function P(x) or Q(x) to calculate the first compensation value R1 and the second compensation value R2 (S60).

The first compensation value R1 may be a difference between the ideal function F(x) and the calculation function P(x) or Q(x). The second compensation value R2 may be a new set flow rate value at which the ideal function F(x) and the calculation function P(x) or Q(x) have the same value.

Next, the compensation value calculation unit 1200 transfers the first compensation value R1 and the second compensation value R2 to the controller 1000 (S61).

Next, the controller 1000 transfers the first compensation value R1 to the flow controller 400 (S70 of FIG. 10), and the flow controller 400 controls the actual flow rate by reflecting the first compensation value R1 (S80 of FIG. 10). Alternatively, the controller 1000 transfers the second compensation value R2 to the flow control unit 1300 (S71 of FIG. 11), and the flow controller 400 resets the second compensation value R2 to the set flow rate value (S81 of FIG. 11).

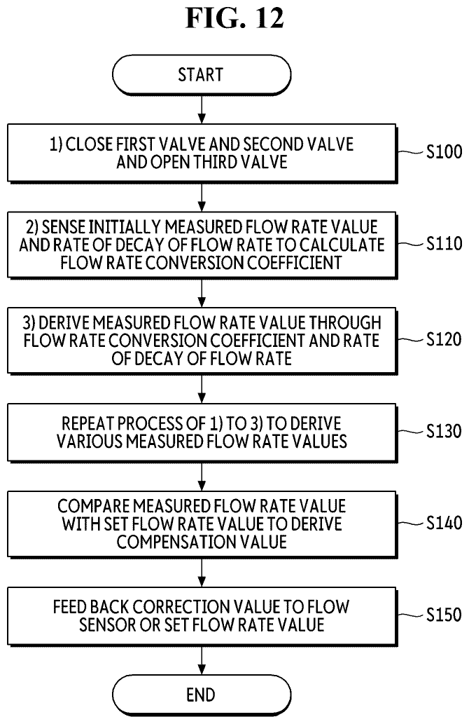

FIG. 12 is a diagram for explaining a flow control method according to some embodiments of the present disclosure. For convenience of explanation, repeated contents of those explained in FIGS. 1 to 11 will be briefly explained or omitted.

The flow control apparatus may be provided. The flow control apparatus may include the first valve (310 of FIG. 2) connected to the piping (200 of FIG. 3) through which a fluid moves; the second valve (320 of FIG. 2) connected to the piping (200 of FIG. 3) and spaced apart from the first valve 310; the flow sensor (330 of FIG. 2) which is disposed between the first valve 310 and the second valve 320, connected to the piping 200, and includes the pressure sensor (420 of FIG. 3) and the third valve (410 of FIG. 3); the flow control unit (1300 of FIG. 2) which adjusts a set flow rate value x of the fluid moving through the piping 200; the function calculation unit (1100 of FIG. 2) which calculates a function from a numerical value sensed from the flow controller 400; the compensation value calculation unit (1200 of FIG. 2) which calculates a compensation value using the function calculated by the function calculation unit 1100; and the controller (1000 of FIG. 2) which controls the first valve 310, the second valve 320, the flow controller 400, the flow control unit 1300, the function calculation unit 1100, and the compensation value calculation unit 1200.

First, 1) the first and second valves are closed and the third valve is adjusted to a set flow rate value (S100).

The controller 1000 may control the first valve 310 and the second valve 320 so that the first valve 310 and the second valve 320 are closed. The controller 1000 may control the first valve 310 and the second valve 320 to be closed, but the third valve 410 included in the flow controller 400 is controlled to be set to a set flow rate value.

At an initial time, 2) an initial flow rate measured value and the rate of decay of the pressure are sensed to calculate a flow rate conversion coefficient (S110).

The initial measured flow rate value yi and the initial measured rate of decay RoDi may be measured by the flow controller 400. The function calculation unit 1100 may calculate the flow rate conversion coefficient C. This flow rate conversion coefficient C should not change and may only need to be determined a single time.

For future measurements, 3) the measured flow rate value can be derived through the flow rate conversion coefficient and the rate of decay of the pressure (S120).

The function calculation unit 1100 may derive the measured flow rate value y using the following Formula y=C×RoD. Here, C is the flow rate conversion coefficient, and RoD may be the rate of decay sensed from the pressure sensor 420 during measurement.

Next, steps 1) and 3) are repeated to derive a plurality of measured flow rate values (S130).

A plurality of measured flow rate values may be derived for a plurality of flow rate bands. That is, a plurality of measured flow rate values may be obtained through a plurality of measurements.

Next, the compensation value is derived by comparing the measured flow rate value with the set flow rate value (S140).

The compensation value may include a first compensation value R1 and a second compensation value R2. The first compensation value R1 may be the difference between the measured flow rate value and the set flow rate value (see FIGS. 6 to 9). The second compensation value R2 may be a new set flow rate value that makes the set flow rate value equal to the measured flow rate value (see FIGS. 6 to 9).

Next, the compensation value is fed back to the flow sensor or the set flow rate value (S150) (e.g., the compensation value is used to adjust a signal from the flow sensor or the set flow rate value).

Referring to FIG. 4, the first compensation value R1 may be used to adjust the flow rate measured by the flow sensor 405 which is used to control the flow rate. Alternatively, the second compensation value R2 may be used to reset the set flow rate value to a new set flow rate.

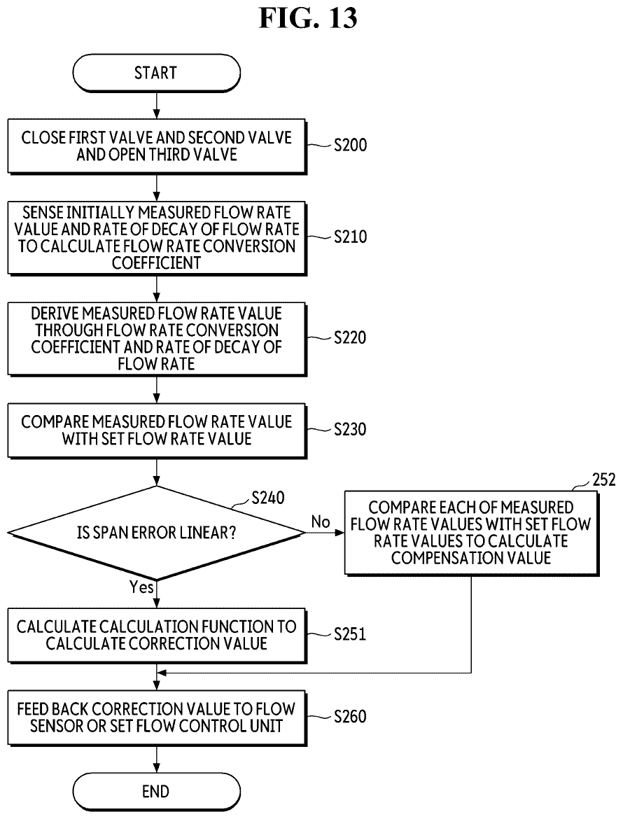

FIG. 13 is a diagram for explaining a flow control method according to some embodiments of the present disclosure. For convenience of explanation, repeated contents of those explained in FIGS. 1 to 12 will be briefly explained or omitted.

The flow control apparatus may be provided. The flow control apparatus may include the first valve (310 of FIG. 2) connected to the piping (200 of FIG. 3) through which the fluid moves; the second valve (320 of FIG. 2) connected to the piping (200 of FIG. 3) and spaced apart from the first valve 310; the flow sensor (330 of FIG. 2) which is disposed between the first valve 310 and the second valve 320, connected to the piping 200, and includes the pressure sensor (420 of FIG. 3) and the third valve (410 of FIG. 3); the flow control unit (1300 of FIG. 2) which adjusts a set flow rate value x of the fluid moving through the piping 200; the function calculation unit (1100 of FIG. 2) which calculates a function from a numerical value sensed from the flow controller 400; the compensation value calculation unit (1200 of FIG. 2) which calculates a compensation value using the function calculated by the function calculation unit 1100; and the controller (1000 of FIG. 2) which controls the first valve 310, the second valve 320, the flow controller 400, the flow control unit 1300, the function calculation unit 1100, and the compensation value calculation unit 1200.

First, the first and second valves are closed, and the third valve is adjusted to a set flow rate (S200). Next, the initially measured flow rate value and the rate of decay of flow rate are measured to calculate a flow rate conversion coefficient (S210). Next, the measured flow rate value is derived through the flow rate conversion coefficient C and the rate of decay of flow rate (S220).

Next, the measured flow rate value is compared with the set flow rate value (S230) (see FIGS. 5 to 9).

Next, it is determined whether the span error is linear (S240).

For example, it is possible to determine whether the span error is linear or nonlinear by comparing the plurality of measured flow rates y with the set flow rate values x.

If the span error is linear (see FIGS. 5 to 8), the function calculation unit 1100 calculates the calculation function P(x) or Q(x) to calculate the compensation value (S251).

If the span error is nonlinear (see FIG. 9), each measured flow rate value is compared with the set flow rate value to calculate the compensation value (S252).

Next, the compensation value is fed back to the flow sensor or the flow control unit (S260).

Both the linear case and the nonlinear case of the span error may include the first compensation value and the second compensation value. The first compensation value may be fed back to the flow controller 400. The second compensation value may be fed back to the flow control unit 1300. The flow control unit 1300 may set the second compensation value to a new set flow rate value.

Although embodiments of the inventive concept have been described with reference to the accompanying drawings, the inventive concept is not limited to the above embodiments but may be implemented in various different forms. A person skilled in the art may appreciate that the inventive concept may be practiced in other forms. Therefore, it should be appreciated that the embodiments as described above are not restrictive but illustrative in all respects.

What is claimed is:

1. A flow control apparatus comprising:
a first valve at an inlet end of a fluid conduit;
a second valve at an outlet end of the fluid conduit;
a flow controller disposed between the first valve and the second valve, the flow controller comprising a pressure sensor and a third valve; and
a controller configured to control the operation of the first valve, the second valve, and the flow controller to adjust a set flow rate value (x) of the flow controller,
wherein the controller is configured to control the first and second valves to be closed and the third valve to be open during a flow rate measurement,
the controller is configured to sense a rate of decay of the pressure of the fluid using the flow controller, and
the controller is configured to determine a span error of the flow controller using the rate of decay to derive a compensation value.

2. The flow control apparatus of claim 1,
wherein the controller is configured to derive a flow rate conversion coefficient (C) based on an initial measured flow rate value (yi) and an initial sensed rate of decay using the flow controller.

3. The flow control apparatus of claim 1,
wherein when the span error is linear,
the controller is configured to derive an ideal function F(x)=x and a calculation function P(x)=((y2−y1)/(x2−x1)) x+A,
independent variable x is a set flow rate value, A is a zero shift value,
x1 is a first set flow rate value, y1 is a first measured flow rate value corresponding to x1, and
x2 is a second set flow rate value, and y2 is a second measured flow rate value corresponding to x2.

4. The flow control apparatus of claim 3,
wherein the compensation value includes a first compensation value that is a difference between the ideal function F(x) and the calculation function P(x), and
the controller is configured to feed the first compensation value back to the flow controller.

5. The flow control apparatus of claim 3,
wherein (y2−y1)/(x2−x1) is represented as B,
the compensation value includes a second compensation value defined as (x−A)/B, and
the controller is configured to reset the set flow rate value (x) to the second compensation value.

6. The flow control apparatus of claim 3,
wherein (y2−y1)/(x2−x1) is defined as B, the zero shift value A is 0,
the compensation value is one of a first compensation value and a second compensation value,
the first compensation value represents a difference between the ideal function F(x) and the calculation function P(x),
the second compensation value is defined as x/B, and
the controller includes a first feedback that feeds the first compensation value back to the flow controller, or a second feedback that resets the set flow rate value (x) to the second compensation value.

7. The flow control apparatus of claim 3,
wherein the first measured flow rate value (y1) is a value obtained by multiplying a flow rate conversion coefficient (C) by a first rate of decay determined based on the pressure measured by the pressure sensor during a first measurement, and
the flow rate conversion coefficient (C) is defined as a value obtained by dividing an initial measured flow rate value (yi) measured by the flow controller by an initial rate of decay determined using the pressure sensed by the pressure sensor.

8. The flow control apparatus of claim 1,
wherein when the span error is linear,
the controller is configured to derive a calculation function Q(x) reflecting a span error using a linear regression analysis, and
the controller is configured to derive the compensation value by comparing the calculation function Q(x) with an ideal function F(x)=x.

9. The flow control apparatus of claim 1,
wherein when the span error is nonlinear,
the compensation value includes a first compensation value that is a difference between the set flow rate value (x) and a measured flow rate value (y) derived from the rate of decay, and
the controller is configured to feed back the first compensation value to the flow controller.

10. The flow control apparatus of claim 1,
wherein when the span error is nonlinear,
the compensation value includes a second compensation value defined by x2/y, where x is a set flow rate value, and y is a measured flow rate value, and
the controller is configured to reset the set flow rate value (x) to the second compensation value.

11. A flow control apparatus comprising:
a first valve connected to an inlet end of a piping;
a second valve connected to an outlet end of the piping, and spaced apart from the first valve;
a flow controller disposed between the first valve and the second valve, connected to the piping, and having a pressure sensor, a flow sensor, and a third valve;
a flow control unit configured to adjust a set flow rate value (x) of the flow controller;
a function calculation unit configured to calculate a function based on a flow rate sensed using the flow controller;
a compensation value calculation unit configured to calculate a compensation value using the function calculated by the function calculation unit; and
a controller configured to control the first valve, the second valve, the flow controller, the flow control unit, the function calculation unit, and the compensation value calculation unit,
wherein the controller is configured to control the first valve and the second valve to be closed and the third valve to be adjusted to a set flow rate value,
the function calculation unit is configured to calculate a measured flow rate value (y) defined as a value obtained by multiplying a flow rate conversion coefficient (C) by a rate of decay of the pressure of a fluid that flows through the third valve between the first valve and the second valve, and
the compensation value calculation unit is configured to calculate a span error and a compensation value using the measured flow rate value (y) and the set flow rate value.

12. The flow control apparatus of claim 11,
wherein the flow rate conversion coefficient (C) represents a value obtained by dividing an initially measured flow rate value (Si) measured using the flow controller by an initial rate of decay of the pressure sensed by the pressure sensor during an initial time period.

13. The flow control apparatus of claim 11,
wherein the span error is linear,
the function calculation unit is configured to derive an ideal function F(x)=x and a calculation function P(x)=(y2−y1)/(x2−x1) x+A,
x is an independent variable that is a set flow rate value set by the flow control unit, A is a zero shift value, x1 is a first set flow rate value, y1 is a first measured flow rate value corresponding to x1, x2 is a second set flow rate value, and y2 is a second measured flow rate value corresponding to x2.

14. The flow control apparatus of claim 13,
wherein the compensation value calculation unit is configured to calculate a first compensation value that represents a difference between the ideal function F(x) and the calculation function P(x), and feed back the first compensation value to the flow controller.

15. The flow control apparatus of claim 13,
wherein (y2−y1)/(x2−x1) is represented as B,
the compensation value calculation unit is configured to calculate a second compensation value represented by (x−A)/B, and transfer the second compensation value to the flow control unit, and
the flow control unit is configured to reset the set flow rate value (x) to the second compensation value.

16. The flow control apparatus of claim 11,
wherein when the span error is nonlinear,
the compensation value calculation unit is configured to calculate a first compensation value that represents a difference between the set flow rate value (x) and the measured flow rate value (y), and feed back the first compensation value to the flow controller.

17. The flow control apparatus of claim 11,
wherein when the span error is nonlinear,
the compensation value calculation unit is configured to calculate a second compensation value that represents x2/y, where x is a set flow rate value, y is a measured flow rate value, and the second compensation value is transferred to the flow control unit, and
the flow control unit is configured to reset the set flow rate value (x) to the second compensation value.

18. A method for adjusting a flow controller, comprising:
setting a flow controller to a set flow rate value, wherein the flow controller includes a pressure sensor, a control valve, and a flow sensor;
closing a valve upstream of the flow controller;
measuring the pressure of a fluid between the valve upstream of the flow controller and the control valve;
determining a rate of decay of the pressure of the fluid with the upstream valve closed;
deriving a measured flow rate of the fluid through the flow controller based on the determined rate of decay and a flow rate conversion coefficient; and
calculating a compensation value based on a difference between the set flow rate value and the measured flow rate.

19. The method for adjusting a flow controller of claim 18,
wherein calculating a compensation value comprises deriving a calculation function P(x)=(y2−y1)/(x2−x1) x+A, wherein x is an variable corresponding to the set flow rate value and A is a zero shift value, x1 is a first set flow rate value at a first time, y1 is a first measured flow rate value corresponding to x1, x2 is a second set flow rate value at a second time, and y2 is a second measured flow rate value corresponding to x2, calculating a first compensation value that is the difference between set flow rate value and a result of the calculation function P(x) for the set flow rate value, and calculating a second compensation value defined as (x−A)/B, where B is defined as (y2−y1)/(x2−x1), and
modifying a signal provided by the flow sensor using the first compensation value or resetting the set flow rate value (x) to the second compensation value.

20. The method for adjusting a flow controller of claim 18,
wherein calculating a compensation value comprises calculating a first compensation value that is a difference between the set flow rate value (x) and a measured flow rate value (y) for the set flow rate value (x), and a second compensation value defined as x2/y, and
modifying a signal provided by the flow sensor using the first compensation value, resetting the set flow rate value (x) to the second compensation value.
